(19) United States
(12) Patent Application Publication
(10) Pub. No.: US 2025/0360535 A1
(43) Pub. Date: Nov. 27, 2025

(54) RESIN SHEET, PRODUCTION METHOD THEREOF, COPPER-CLAD LAMINATE AND CIRCUIT BOARD

(71) Applicant: DAIKIN INDUSTRIES, LTD., Osaka (JP)

(72) Inventors: Kyohei SAWAKI, Osaka (JP); Shingo OKUNO, Osaka (JP)

(73) Assignee: DAIKIN INDUSTRIES, LTD., Osaka (JP)

(21) Appl. No.: 19/286,434

(22) Filed: Jul. 31, 2025

Related U.S. Application Data
(63) Continuation of application No. PCT/JP2024/002709, filed on Jan. 29, 2024.

(30) Foreign Application Priority Data
Feb. 1, 2023 (JP) 2023-013730

(51) Int. Cl. B05D 3/00; B05D 3/14; B05D 7/24; H05K 1/05

(52) U.S. Cl. CPC B05D 3/207; B05D 3/14; B05D 7/24; H05K 1/05; B05D 2401/20; B05D 2430/00; B05D 2506/15; B05D 2601/22; H05K 2201/015; H05K 2201/0209

(57) ABSTRACT

Provided is a resin sheet made from fluororesin, having excellent thermal expansion property in the thickness direction. The resin sheet includes a fluororesin and an anisotropic filler. The anisotropic filler is uniaxially oriented in the film thickness direction and randomly oriented in the plane direction.

### Cross Reference To Related Applications

This application is a Rule 53(b) continuation of International Application No. PCT/JP2024/002709, filed on Jan. 29, 2024, which claims priority from Japanese Patent Application No. 2023-013730, filed on Feb. 1, 2023, the disclosures of all of which are incorporated herein by reference in their respective entireties.

### TECHNICAL FIELD

The present disclosure relates to a resin sheet, a production method thereof, a copper-clad laminate and a circuit board.

### BACKGROUND ART

A resin sheet used in a printed wiring board or the like is required to have high dimensional stability. In other words, the resin sheet is required to have a low coefficient of thermal expansion, and therefore, a filler is often blended therein. As the filler, an anisotropic filler having an anisotropic shape is used in some cases.

Patent Literature 1 discloses a resin sheet containing an anisotropic filler oriented by applying a magnetic field in production of the resin sheet.

Patent Literatures 2 and 3 disclose methods for obtaining orientation property of anisotropic fillers other than application of a magnetic field.

### CITATION LIST

### Patent Literature

Patent Literature 1: Japanese Patent Laid-Open No. 2002-80617

Patent Literature 2: International Publication No. WO 2020/225678

Patent Literature 3: Japanese Patent Laid-Open No. 2022-60242

Patent Literature 4: International Publication No. WO 2020/145133

### Summary

The present disclosure relates to a resin sheet containing a fluororesin and an anisotropic filler, wherein the anisotropic filler is uniaxially oriented in the film thickness direction and randomly oriented in the plane direction.

### BRIEF DESCRIPTION OF DRAWINGS

FIG. 1 is a schematic diagram showing a method for producing a resin sheet containing an anisotropic filler according to a conventional technique.

FIG. 2 is a schematic diagram showing a method for producing a resin sheet containing an anisotropic filler according to the present disclosure.

FIG. 3 is a schematic diagram showing an example of a method for applying a magnetic field in the present disclosure.

FIG. 4 is a schematic diagram showing a method for measuring X-ray diffraction.

FIG. 5 is a schematic diagram showing a state of the resin sheet according to the present disclosure subjected to X-ray diffraction measurement.

### DESCRIPTION OF EMBODIMENTS

The present disclosure is described in detail as follows.

Resin components usually tend to expand when heated, which has been a problem in obtaining dimensional stability of a formed product of resin. In order to solve the problem, an inorganic filler having low thermal expansion property has been usually compounded.

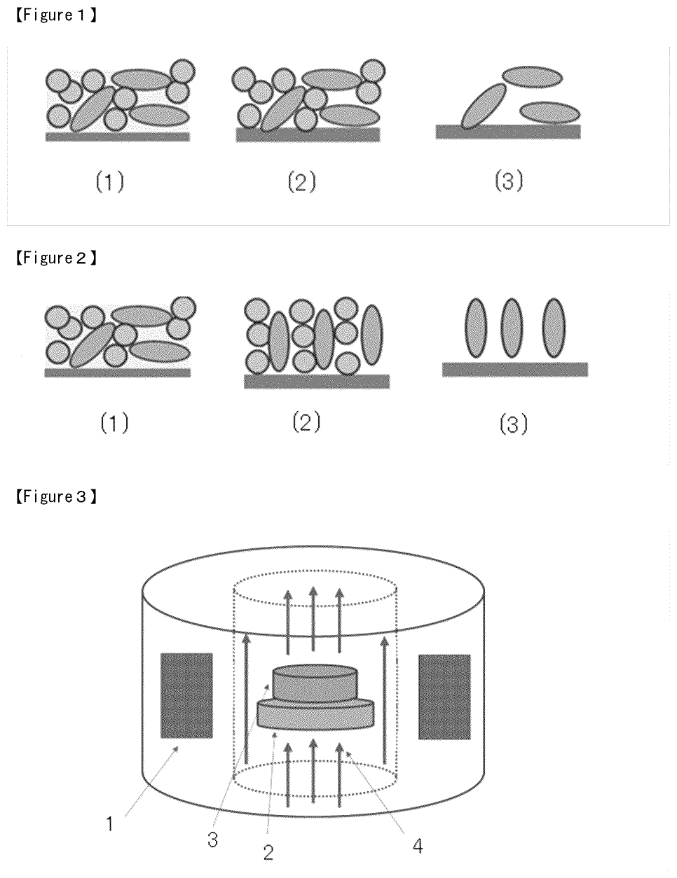

As such inorganic filler, an inorganic filler having a highly anisotropic shape (e.g., plate-like) has been widely used. It is widely known that such highly anisotropic inorganic filler in a resin formed into a sheet are oriented in the planar direction of the sheet (FIG. 1). In FIG. 1, a state immediately after application of a dispersion to a substrate is represented in (1), a state after drying is represented in (2), and a state after sintering is represented in (3).

Due to occurrence of the orientation of inorganic filler, the effect of suppressing the thermal expansion of a resin sheet resulting from the incorporation of inorganic filler is hardly obtained in the thickness direction. In order to solve the problem, in Patent Literatures 2 and 3, a resin sheet having inorganic filler oriented in the thickness direction of the sheet is obtained by methods completely different from that of the present application. However, the methods described in those also cause orientation property in the planar direction to reduce randomness, resulting in anisotropy of linear expansion in the planar direction, so that thermal expansion causes cracks in the copper foil in a specific direction only.

Based on the problem, the present inventors have solved the problem by presence of at least a part of anisotropic fillers in a direction perpendicular to the plane of the resin sheet, so that a resin sheet with low thermal expansion property in the thickness direction can be obtained. Thereby, cracking of the copper foil in the thickness direction is prevented when the resin sheet is used in a circuit board.

Examples of the methods for producing such a resin sheet include a method for producing a resin sheet comprising:
a step (1) of applying a dispersion containing a fluororesin and an anisotropic filler onto a substrate to form a coating film;
a step (2) of drying the coating film obtained in the step (1) while applying a magnetic field to obtain a dried coating film; and
a step (3) of sintering the dried coating film obtained in the step (2).

A schematic diagram showing the production method is shown in FIG. 2. In FIGS. 2, (1) to (3) correspond to the steps (1) to (3) described above.

The resin sheet of the present disclosure is characterized in that the anisotropic filler is uniaxially oriented in the film thickness direction and randomly oriented in the plane direction. Such a state may be identified by measurement of the intensity ratio of the diffraction peaks in an X-ray diffraction chart obtained by exposure of the sheet in the thickness direction to X-rays.

The resin sheet of the present disclosure contains a fluororesin and an anisotropic filler. These are described in detail as follows.

### Anisotropic Filler

The anisotropic filler used in the present disclosure is a particle with an anisotropic shape (size varies depending on the direction), excluding glass fiber, crushed silica, and ceramics. For example, the anisotropic filler is made of inorganic compound such as carbon, inorganic oxide, inorganic nitride, and inorganic carbide, or resin, and specific examples include fibrous, needle-like, scale-like, or whisker-like particles made of metal oxides, metal nitrides, metal carbides, or metal hydroxides such as boron nitride, aluminum nitride, aluminum oxide, zinc oxide, silicon carbide, and aluminum hydroxide; metals and alloys; carbon materials such as graphite, plumbago and diamond; and highly thermally conductive resins.

Among these, talc or boron nitride is preferred from the viewpoint of electrical characteristics, and the shape may be, for example, flat, scale-like, plate-like, linear, tabular, granular, fibrous, and whisker-like. A scale-like, plate-like, or linear shape is preferred, a scale-like or plate-like shape is more preferred, and a plate-like shape is particularly preferred. In the present embodiment, only one type of anisotropic filler may be used, or two or more types of anisotropic fillers may be contained within a range not impairing the effect of the present disclosure. For example, talc may be used in combination with another anisotropic filler.

It is preferable that the anisotropic filler be talc or boron nitride, from the viewpoint of low hardness and excellent magnetic field orientation.

It is preferable that the anisotropic filler have an aspect ratio of 1 or more and 2,000 or less. Use of an anisotropic filler having such a shape is preferred in terms of reducing thermal expansion (linear expansion) in the thickness direction. The aspect ratio is a value obtained by dividing the average particle size of the anisotropic filler measured with an electron microscope by the average minor axis size (average value of the length in the shorter direction). The lower limit of the aspect ratio is more preferably 10, and still more preferably 20. The upper limit of the aspect ratio is more preferably 1,000, and still more preferably 200.

It is preferable that the average particle size of the anisotropic filler be 0.1 μm or more and 50 μm or less. Use of the filler having such an average particle size is preferred in terms of more effective reduction in linear expansion. The average particle size is a D50 value measured by laser analysis/scattering method. The lower limit of the average particle size is more preferably 1 μm or more, and still more preferably 3 μm or more. The upper limit of the average particle size is more preferably 30 μm, and still more preferably 20 μm.

### Fluororesin

The resin sheet of the present disclosure contains a fluororesin. Since a fluororesin has low dielectric properties, it can be suitably used for the purpose of the present disclosure.

Although the fluororesin that can be used in the present disclosure is not limited, a perfluorinated fluororesins is preferred. Examples thereof include polytetrafluoroethylene [PTFE], tetrafluoroethylene [TFE] /hexafluoropropylene [HFP] copolymer [FEP], TFE/alkyl vinyl ether copolymer [PFA], TFE/HFP/alkyl vinyl ether copolymer [EPA], TFE/chlorotrifluoroethylene [CTFE] copolymer, TFE/ethylene copolymer [ETFE], polyvinylidene fluoride [PVdF], and tetrafluoroethylene with a molecular weight of 300,000 or less [LMW-PTFE]. These fluororesins may be used alone, or two or more thereof may be mixed. From the viewpoint of low dielectric properties, the fluororesin is preferably a perfluorinated fluororesin, and in particular, polytetrafluoroethylene resin (PTFE), tetrafluoroethylene [TFE] /hexafluoropropylene [HFP] copolymer [FEP], and TFE/alkyl vinyl ether copolymer [PFA] are preferred. Among these, polytetrafluoroethylene resin (PTFE) and TFE/alkyl vinyl ether copolymer [PFA] are more preferred.

### Polytetrafluoroethylene

PTFE may be modified polytetrafluoroethylene (hereinafter referred to as modified PTFE), may be homopolytetrafluoroethylene (hereinafter referred to as homo PTFE), or may be a mixture of modified PTFE and homo PTFE.

The modified PTFE contains a TFE unit based on TFE and a modified monomer unit based on a modified monomer. The modified monomer unit is a part of the molecular structure of the modified PTFE, which is a part derived from the modified monomer. The modified PTFE contains modified monomer units preferably in an amount of 0.001 to 0.500 wt %, and more preferably in an amount of 0.01 to 0.30 wt %, of the total monomer units. The total monomer units are the part derived from all monomers in the molecular structure of the modified PTFE.

The modified monomer is not limited as long as it can be copolymerized with TFE, and examples thereof include perfluoro-olefins such as hexafluoropropylene (HFP); chlorofluoro-olefins such as chlorotrifluoroethylene (CTFE); hydrogen-containing fluoroolefins such as trifluoroethylene and vinylidene fluoride (VDF); perfluorovinyl ethers; perfluoroalkyl ethylene (PFAE), and ethylene. The modified monomer used may include one type or a plurality of types.

The perfluorovinyl ether is not limited, and examples thereof include perfluoro unsaturated compounds represented by the following general formula (1):

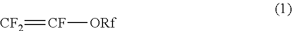

In the formula, Rf represents a perfluoro organic group.

In the present specification, the perfluoro organic group is an organic group in which all hydrogen atoms bonded to carbon atoms are replaced with fluorine atoms. The perfluoro organic group may have an ether oxygen.

Examples of the perfluorovinyl ether include perfluoro (alkyl vinyl ether) (PAVE), in which Rf in the general formula (1) represents a perfluoroalkyl group having 1 to 10 carbon atoms. The number of carbon atoms in the perfluoroalkyl group is preferably 1 to 5. Examples of the perfluoroalkyl group in PAVE include a perfluoromethyl group, a perfluoroethyl group, a perfluoropropyl group, a perfluorobutyl group, a perfluoropentyl group, and a perfluorohexyl group. As PAVE, perfluoropropyl vinyl ether (PPVE) and perfluoromethyl vinyl ether (PMVE) are preferred.

Examples of the perfluoroalkyl ethylene (PFAE) include perfluorobutyl ethylene (PFBE) and perfluorohexyl ethylene (PFHE), though not limited thereto.

As the modifying monomer in the modified PTFE, at least one selected from the group consisting of HFP, CTFE, VDF, PAVE, PFAE and ethylene is preferred.

### Melt Formable Fluororesin

The fluororesin of the present disclosure may be a melt formable fluororesin. The melt formable fluororesin is also described in detail as follows.

The fluororesin may be a melt formable fluororesin, and examples thereof include tetrafluoroethylene-perfluoroalkyl vinyl ether copolymer (PFA), copolymer having chlorotrifluoroethylene (CTFE) units (CTFE copolymer), tetrafluoroethylene-hexafluoropropylene copolymer (FEP), tetrafluoroethylene-ethylene copolymer (ETFE), polychlorotrifluoroethylene (PCTFE), chlorotrifluoroethylene-ethylene copolymer (ECTFE), polyvinylidene fluoride (PVDF), and polyvinyl fluoride (PVF), tetrafluoroethylene-hexafluoropropylene-vinylidene fluoride copolymer (THV), and tetrafluoroethylene-vinylidene fluoride copolymer.

Among these melt formable fluororesins, tetrafluoroethylene-perfluoroalkyl vinyl ether copolymer (PFA) and tetrafluoroethylene-hexafluoropropylene copolymer (FEP) are preferred.

As the PFA, a copolymer having a molar ratio between TFE units and PAVE units (TFE unit/PAVE unit) of 70/30 or more and less than 99.5/0.5 is preferred, though not limited thereto. A more preferred molar ratio is 70/30 or more and 98.9/1.1 or less, and a still more preferred molar ratio is 80/20 or more and 98.5/1.5 or less. With an excessively small amount of TFE units, the mechanical properties tend to decrease, while with an excessively large amount of TFE units, the melting point becomes too high and the formability tends to decrease. The PFA may be a copolymer consisting of TFE and PAVE only. Alternatively, it is preferable that the PFA be a copolymer having monomer units derived from monomers copolymerizable with TFE and PAVE in an amount of 0.1 to 10 mol %, and TFE units and PAVE units in a total amount of 90 to 99.9 mol %. Examples of the monomers copolymerizable with TFE and PAVE include HFP, a vinyl monomer represented by CZ³Z⁴═CZ⁵(CF₂)ₙZ⁶ (wherein Z³, Z⁴ and Z⁵ are the same or different and represent a hydrogen atom or a fluorine atom, Z⁶ represents a hydrogen atom, a fluorine atom or a chlorine atom, and n represents an integer of 2 to 10), and an alkyl perfluorovinyl ether derivative represented by CF₂═CF—OCH₂—Rf⁷ (wherein Rf⁷ represents a perfluoroalkyl group having 1 to 5 carbon atoms). Other copolymerizable monomers include, for example, a cyclic hydrocarbon monomer having an acid anhydride group, and examples of acid anhydride-based monomer include itaconic anhydride, citraconic anhydride, 5-norbornene-2, 3-dicarboxylic anhydride, and maleic anhydride. The acid anhydride-based monomer may be used alone or in combination of two or more types.

The melt flow rate (MFR) of the PFA is preferably 0.1 to 100 g/10 min, more preferably 0.5 to 90 g/10 min, and still more preferably 1.0 to 85 g/10 min. In the present specification, the MFR is a value obtained from measurement in accordance with ASTM D3307 under conditions at a temperature of 372° C. with a load of 5.0 kg.

### Blending Proportion

It is preferable that the resin sheet of the present disclosure contains anisotropic filler at a proportion of 10 to 80 mass % relative to the total amount of the fluororesin and the anisotropic filler. A proportion controlled in the range is preferred in terms of balancing the effect of low linear expansion with the strength of the material itself. The lower limit is more preferably 15 mass %, and still more preferably 20 mass %. The upper limit is more preferably 70 mass %, and still more preferably 60 mass %.

### Other Fillers

The resin sheet of the present disclosure may further contain silica or glass fiber. Both of silica and glass fiber may be blended.

In the case where the “other fillers” are blended, the content thereof is preferably 1 to 40 mass % based on the total amount of the resin sheet. A content controlled in the range is preferred in terms of balancing the effects of low linear expansion between the thickness direction and the planar direction. The lower limit is more preferably 3 mass %, and still more preferably 5 mass %. The upper limit is more preferably 35 mass %, and still more preferably 30 mass %.

### Other Components

The resin sheet of the present disclosure may contain other components on an as needed basis. Examples of the other components include additives such as UV absorbers, fillers, cross-linking agents, antistatic agents, heat-resistant stabilizers, foaming agents, foam nucleating agents, antioxidants, surfactants, photopolymerization initiators, antiwear agents, surface modifiers, and liquid crystal polymers.

In the case where the other components are blended, it is preferable that the content of the fluororesin, anisotropic fillers and other fillers be 95 mass % or more relative to the total amount of the resin sheet. Blending an excessive amount of other components is not preferred in terms of unavailability of desired physical properties.

### Resin Sheet

It is preferable that the resin sheet of the present disclosure include the components described above and have a film thickness of 0.1 to 2 mm. The thickness here is a value measured with a film thickness meter. A thickness controlled in the range is preferred in terms of balancing the sheet strength and flexibility.

In the resin sheet of the present disclosure, it is preferable that the anisotropic filler be talc, and in an X-ray diffraction chart obtained by exposure of the sheet in the cross-sectional direction to X-rays, the intensity ratio (<001>/<020>) of the diffraction peak of the <001>plane to the diffraction peak of the <020>plane of the talc in the thickness direction of the sheet be 300 or less; or it is preferable that the anisotropic filler be boron nitride, and in an X-ray diffraction chart obtained by exposure of the sheet in the cross-sectional direction to X-rays, the intensity ratio (<002>/<100>) of the diffraction peak of the <002>plane to the diffraction peak of the <100>plane of the boron nitride in the thickness direction of the sheet be 20 or less. The X-ray diffraction measurement here may be performed according to the method shown in Examples.

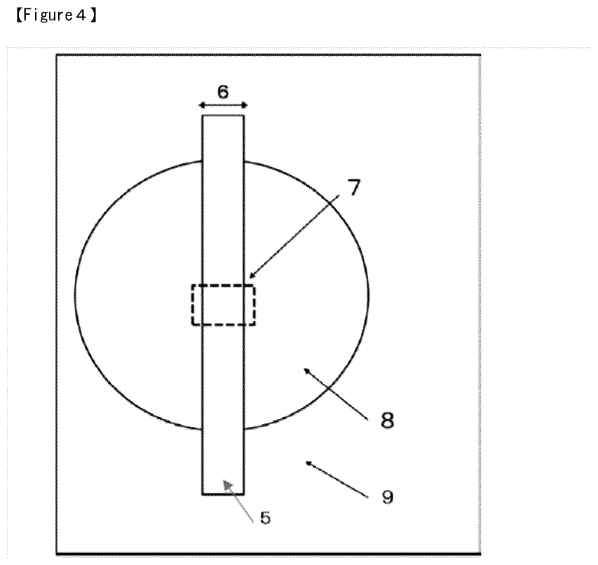

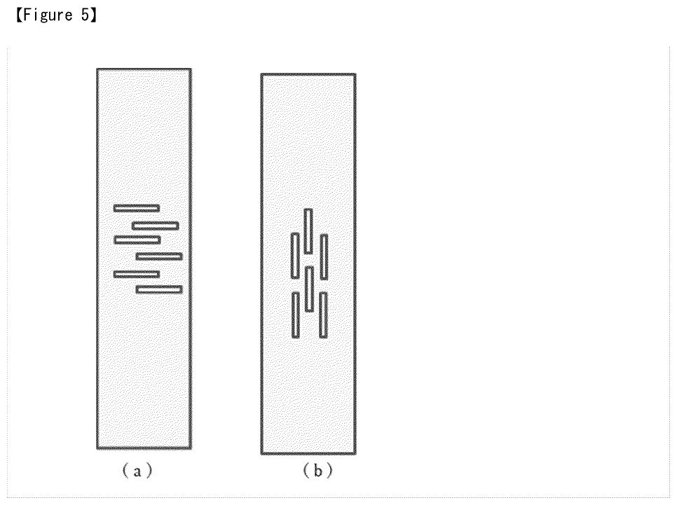

The X-ray diffraction pattern in the present disclosure is measured in the state as shown in the schematic diagram in FIG. 4. The sample sheet cross section 5 in FIG. 4 is based on the sheet of the present disclosure. The resin sheet of the present disclosure is in the state shown in the schematic diagram in FIG. 5 (a), or in a state close thereto. Since X-ray diffraction is performed in such a state, the X-ray diffraction has peaks at 90° and 270°. On the other hand, a conventional resin sheet is in the state shown in the schematic diagram in FIG. 5 (b), or in a state close thereto. Therefore, the X-ray diffraction has peaks at 0° and 180°.

From such a perspective, in the case where the diffraction peak intensity ratio of the X-ray diffraction described above is within a specific range, it can be determined that the anisotropic filler is uniaxially oriented in the film thickness direction and randomly oriented in the plane direction. From such a perspective, parameters of the diffraction peak intensity ratio described above are set, and a resin sheet is obtained such that these fall within a specific range.

The intensity ratio (<001>/<020>) of the diffraction peak of the <001>plane to the diffraction peak of the <020>plane of talc in the thickness direction of the sheet is more preferably 300 or less, and still more preferably 100 or less. The intensity ratio (<002>/<100>) of the diffraction peak of the <002>plane to the diffraction peak of the <100>plane of boron nitride in the thickness direction of the sheet is more preferably 20 or less, and still more preferably 10 or less.

### Method for Producing Resin Sheet)

The method for producing the resin sheet of the present disclosure, comprising:
a step (1) of applying a dispersion containing a fluororesin and an anisotropic filler onto a substrate to form a coating film;
a step (2) of drying the coating film obtained in the step (1) while applying a magnetic field to obtain a dried coating film; and
a step (3) of sintering the dried coating film obtained in the step (2).

That is, after applying the dispersion to a substrate, a dried coating film is obtained by drying in the step (2), while a magnetic field is applied thereto.

Thereby, at least a portion of the anisotropic filler is oriented by the action of the magnetic field and aligned in a direction closer to perpendicular to the thickness direction of the coating film. The object described above thus achieved.

Talc, boron nitride, and the like usually used as anisotropic filler are diamagnetic and generally considered to have no magnetic properties. However, they actually have weak magnetic properties, and application of an external magnetic field causes orientation.

As a forming method of a fluororesin, melt forming is widely known. Although melt forming needs to be performed at high temperature, high temperature cannot be applied to some types of magnets. In addition, since the viscosity of the molten material is high, it is not easy to orient anisotropic fillers by melt forming in the presence of a magnetic field.

On the other hand, no such a problem occurs in forming a coating film with application of a dispersion. Further, in the early stage of drying, the anisotropic filler can move relatively freely in the coating film, so that easy movement can be achieved by the effect of a magnetic field. Therefore, the method is suitable for obtaining the resin sheet of the present disclosure. Thereby, the object of the present disclosure can be achieved in a simple method.

Hereinafter, the method for producing a resin sheet of the present disclosure will be described in detail according to each step.

### Step (1)

The step (1) includes applying a dispersion containing a fluororesin and an anisotropic filler onto a substrate to form a coating film.

In the step (1), a dispersion containing a fluororesin and an anisotropic filler is used. The fluororesin and anisotropic filler used here are as described above.

The dispersion includes a fluororesin and an anisotropic filler dispersed in a liquid medium. The liquid medium is not limited, and preferably contains water or a water-soluble solvent in combination with water. The water-soluble solvent has a function of wetting the fluororesin, and one further having a high boiling point acts as drying retarder that bonds the resins together during drying after coating and prevents occurrence of cracks. Even a high boiling point solvent evaporates at the sintering temperature of the fluororesin, having no impact on the coating film.

The fluororesin dispersed in water may be an emulsion resin obtained by emulsion polymerization or a powder of fluororesin dispersed in a liquid medium, though an emulsion resin is preferred.

The anisotropic filler can be dispersed in a liquid medium by shaking the mixture liquid.

It is preferable that the dispersion contains a liquid medium at a proportion of 20 to 80 mass %.

The dispersion may contain an emulsifier, etc., in addition to the components constituting the sheet and the liquid medium.

Such a dispersion is applied onto a substrate to form a coating film. The substrate here may be metals such as copper foil, iron, stainless steel, copper, aluminum and brass; glass products such as glass plate, woven fabric and nonwoven fabric of glass fiber; formed products and coated products of general-purpose and heat-resistant resins such as polypropylene, polyoxymethylene, polyimide, modified polyimide, polyamideimide, polysulfone, polyether sulfone, polyether ether ketone and liquid crystal polymer; formed products and coated products of general-purpose rubbers such as SBR, butyl rubber, NBR and EPDM, silicone rubber, heat-resistant rubber such as fluororubber; woven fabric and nonwoven fabric of natural fiber and synthetic fiber; or a laminated substrate formed by combining these, though not limited thereto.

The article substrate may be surface-treated. Examples of the surface treatment include roughening to a desired roughness using sandblasting, roughening surface with adhesion of particles, and metal oxidation prevention processing. Examples of the method for forming a coating film include spray coating, roll coating, coating with a doctor blade, dip (immersion) coating, impregnation coating, spin flow coating, curtain flow coating, coating with a bar coater, gravure coating, and micro gravure coating.

### Step (2)

In the step (2), the coating film obtained in the step (1) is dried while applying a magnetic field thereto to obtain a dried coating film. A schematic diagram showing an example of a method for applying a magnetic field when performing the step (2) is shown in FIG. 3.

The device shown in FIG. 3 has a conductive coil installed on the outer cylindrical periphery and a sample placement part in the center. An article with a coating film formed on a substrate obtained in the step (1) is placed on the part and dried while a magnetic field is applied.

In the case where the dispersion contains talc, the dispersion is arranged such that the direction of magnetic field lines corresponds to the desired orientation direction of talc in a magnetic field atmosphere. In this way, the dispersion is arranged such that the direction of the magnetic field lines corresponds to the desired orientation direction, so that talc can be oriented in any direction.

It is preferable that the magnetic field applied be 0.1 to 10 T. Such a magnetic field is a value obtained from measurement of the magnetic field density using a Gaussmeter. With a magnetic field controlled in this range, the orientation of the anisotropic filler preferably proceeds. The lower limit of the magnetic field applied is more preferably 0.3 T, and still more preferably 0.5 T. There is no upper limit of the magnetic field applied.

As the magnet used to apply such a magnetic field, a permanent magnet or a superconducting magnet is particularly preferred, though not limited thereto.

The drying in the step (2) is preferably performed under heating conditions, and the drying temperature is preferably within the range of 1 to 80° C. An excessively high drying temperature is not preferred because the filler dries before oriented. On the other hand, an excessively low drying temperature is not preferred because the excessively low volatilization temperature of the liquid medium results in a decrease in efficiency. The drying method may be one in which the temperature can be controlled on a sample stage, though not limited thereto.

### Step (3)

The step (3) is a step of sintering the dried coating film obtained in the step (2) by heating. A resin sheet is formed by such a process. The step (3) can be performed under general conditions for obtaining a resin sheet by such a method. Specifically, it can be performed at 300 to 400° C.

The steps (1) to (3) may be performed continuously on a line by sequentially installing means for performing the steps (1) to (3) on the line, or may be performed in a batch system for each step.

In the method for producing the resin sheet of the present disclosure, it is preferable that the linear expansion in the film thickness direction be equal to or less than ½ that of a resin sheet obtained by sintering a dried coating film dried without application of a magnetic field in the step (2). Through such a production method, the effects of the present disclosure can be exhibited well.

### Circuit Board

The sheet-shaped resin composition of the present disclosure may be laminated with a conductive layer for suitably use in circuit board applications.

The present disclosure also relates to a circuit board having a conductive layer of metal or the like on one or both sides of the resin sheet described above. As described above, the resin sheet of the present disclosure is particularly suitable for use in printed wiring board applications, and therefore can be suitably used as such a laminate. It is more preferable that the conductive layer be a copper foil.

The circuit board may be produced from a metal foil as the conductive layer laminated with a resin sheet, or may be produced from a metal foil bonded to a resin sheet to form a laminate.

It is preferable that the copper foil have an Rz of 1.6 μm or less. In other words, the fluororesin composition of the present disclosure has excellent adhesion to a copper foil having a high smoothness with an Rz of 1.6 μm or less.

Further, although the copper foil is required to have an Rz of 1.6 μm or less on at least the surface to be bonded to the resin sheet, Rz value on another surface is not limited thereto.

The Rz is the sum of a value at the highest point (maximum peak height: Rp) and a value at the deepest point (maximum valley depth: Rv). The Rz is the ten-point average roughness specified in JIS-B0601. In the present specification, the Rz is a value measured with a surface roughness meter (product name: Surfcom 470A, manufactured by Tokyo Seiki Kosakusho Co., Ltd.) for a measurement length of 4 mm.

The thickness of the copper foil is preferably in the range of 1 to 100 μm, more preferably in the range of 5 to 50 μm, and still more preferably 9 to 35 μm, though not limited thereto.

Specific examples of the copper foil include rolled copper foil and electrolytic copper foil, though not limited thereto.

The copper foil with Rz of 1.6 μm or less is not limited, and a commercially available product may be used. Examples of the commercially available copper foil with Rz of 1.6 μm or less include an electrolytic copper foil CF-T9DA-SV-18 (thickness: 18 μm, Rz: 0.85 μm) (manufactured by Fukuda Metal Foil and Powder Co., Ltd.).

The copper foil may be surface-treated to increase the adhesion strength with the resin sheet of the present disclosure.

The circuit board of the present disclosure may further include layers other than the copper foil and the resin sheet.

In the circuit board of the present disclosure, the copper layer may be formed on one side or both sides. Examples of the methods for forming the copper layer include laminating (adhering) a copper foil to the surface of the resin sheet, vapor deposition, and plating. Examples of the method for laminating copper foil include hot pressing. Examples of the hot pressing temperature include a temperature in the range from the melting point of the resin sheet −150° C. to the melting point of the resin sheet +40° C. The hot pressing time period is, for example, 1 to 30 minutes. The hot pressing pressure in the production may be 0.1 to 10 MPa.

The circuit board of the present disclosure is not limited in terms of its application, and is preferably used as a printed circuit board, a laminated circuit board, or a high-frequency circuit board. The circuit board is not limited, and may be produced by a conventional method.

The laminate used for the circuit board is also a laminate including a copper foil layer, the resin sheet described above, and a substrate layer. The substrate layer is not limited, and preferably has a fabric layer made of glass fiber, and a resin sheet layer.

the present disclosure provides a resin sheet made from fluororesin, having excellent low thermal expansion property in the thickness direction.

It is preferable that the fluororesin be a perfluorinated fluororesin, and in particular, at least one selected from the group consisting of polytetrafluoroethylene, tetrafluoroethylene/perfluoro (alkyl vinyl ether) copolymer, and tetrafluoroethylene/hexafluoropropylene copolymer.

It is preferable that the anisotropic filler have an aspect ratio of 1 or more and 200 or less.

It is preferable that the anisotropic filler have an average particle size of 0.1 to 50 μm.

It is preferable that the anisotropic filler be talc or boron nitride.

In the resin sheet, it is preferable that the anisotropic filler be talc, and in an X-ray diffraction chart obtained by exposure of the sheet in the cross-sectional direction to X-rays, the intensity ratio (<001>/<020>) of the diffraction peak of the <001>plane to the diffraction peak of the <020>plane of the talc in the thickness direction of the sheet be 300 or less; or it is preferable that the anisotropic filler be boron nitride, and in an X-ray diffraction chart obtained by exposure of the sheet in the cross-sectional direction to X-rays, the intensity ratio (<002>/<100>) of the diffraction peak of the <002>plane to the diffraction peak of the <100>plane of the boron nitride in the thickness direction of the sheet be 20 or less.

It is preferable that the resin sheet further contain silica or glass fiber in addition to the anisotropic filler.

It is preferable that the silica be amorphous.

It is preferable that the resin sheet have a film thickness of 0.1 to 2 mm.

It is preferable that the resin sheet be an insulating material for a circuit board.

The present disclosure also relates to a copper-clad laminate having a copper foil and the resin sheet as essential layers.

The present disclosure also relates to a circuit board comprising the resin sheet and a conductive layer.

It is preferable that the conductive layer be made of metal.

It is preferable that the metal have a surface roughness Rz of 2.0 μm or less on a surface in contact with the resin sheet.

It is preferable that the metal be copper.

It is preferable that the copper be rolled copper or electrolytic copper.

It is preferable that the circuit board be a printed circuit board, a multilayer circuit board or a high frequency board.

The present disclosure relates to a method for producing a resin sheet, comprising:
a step (1) of applying a dispersion containing a fluororesin and an anisotropic filler onto a substrate to form a coating film;
a step (2) of drying the coating film obtained in the step (1) while applying a magnetic field to obtain a dried coating film; and
a step (3) of sintering the dried coating film obtained in the step (2).

In the method for producing a resin sheet, it is preferable that the linear expansion coefficient in the film thickness direction is equal to or less than ½ that of a resin sheet obtained by sintering a coating film dried without application of a magnetic field in the step (2).

In the method for producing a resin sheet, it is preferable that the intensity of the magnetic field be 0.1 to 10 T.

In the method for producing a resin sheet, it is preferable that the total solid concentration of the fluororesin and the anisotropic filler in the dispersion be 5 to 70 wt %.

It is preferable that the weight ratio between the fluororesin and the anisotropic filler in the dispersion be 90/10 to 30/70.

The resin sheet of the present disclosure includes anisotropic fillers oriented in the film thickness direction of the sheet, having a reduced thermal expansion in the film thickness direction and high uniformity in thermal expansion performance in the planar direction. Thereby, the conventional problem of cracks occurring in copper plating in a direction perpendicular to the sheet plane can be solved.

### EXAMPLES

The present disclosure is described in detail with reference to Examples as follows. In the following Examples, unless otherwise specified, “part” and “%” represent “part by mass” and “mass %”, respectively.

The materials used in Examples are as follows:

### Water Dispersion of Fluororesin

PFA water dispersion 1: average particle size: 336 nm, PFA component: 64.5%
PTFE water dispersion 1: average particle size: 250 nm, PTFE component: 60.0%

### Fluororesin Powder

PFA powder 1: average particle size: 504 nm, MFR: 27.0

### Additive

Surfactant 1: polyether-type surface modifier

### Filler

Talc 1: average particle size: 5 μm, aspect ratio: 40 to 45
Talc 2: average particle size: 7 μm, aspect ratio: 30, surface treated with aminosilane (amino group-containing silane coupling agent)
Talc 3: average particle size: 5 μm, aspect ratio: 40 to 45, surface treated with aminosilane (amino group-containing silane coupling agent)
Boron nitride 1: average particle size: 10 μm, shape: scaly
Silica 1: average particle size: 2.1 μm, shape: spherical

### Example 1

### <Preparation of Mixture Liquid>

A mixture including 5.0 g of PFA water dispersion 1, 3.3 g of talc 1, 4.3 g of water, and 0.5 g of surfactant 1 was stirred with a mix rotor at room temperature for 10 hours.

### <Magnetic Field Application and Preliminary Drying>

In a glass petri dish having a diameter (inner diameter) of 48 mm, 4.4 g of the resulting mixture liquid was placed and left standing on a hot stage heated to 60° C. for 70 minutes while applying a magnetic field of 10 T with a magnetic field application device (manufactured by Japan Superconductor Technology Co., Ltd., model: JMTD1OT 100) to pre-dry the mixture until losing the fluidity.

### <Drying>

In order to remove volatile components in the resulting solid content, the mixture was further dried at 130° C. for 30 minutes.

### Sintering

The dried coating film was sintered at 330° C. for 30 minutes to obtain a sample having a thickness of 0.4 mm.

### <Measurement of Linear Expansion Coefficient>

The linear expansion coefficient was measured using a thermomechanical analyzer (TMA-7100, manufactured by Hitachi High-Tech Science Corporation) on a sample cut into a 5 mm square from the sintered resin sheet. While applying a load of 49 mN at a heating rate of 2° C./min, the linear expansion coefficient was determined from the amount of displacement of the sample at 20 to 200° C.

### <X-ray Diffraction Measurement (Wide-Angle X-Ray Scattering Method)>

The various samples were observed using WAXS method. The WAXS method was performed at room temperature (25° C.) using beamline BL40B2 in SPring-8 of Japan Synchrotron Radiation Research Institute (JASRI), with an X-ray wavelength (λ) of 0.0709 nm, a camera length (R) of 323 mm, and a detector PLATUS 3M (manufactured by Dectris Ltd.).

The sintered resin sheet was cut into a thickness of 0.2 mm, and placed on a sample holder such that the thickness direction was in horizontal direction, and the edge was exposed to the beam (FIG. 4). The X-ray exposure time was 60 seconds.

### Examples 2 to 8 and 10

A dispersion was prepared according to the composition shown in Table 1, and the sample was obtained in the same manner as in Example 1 to measure the linear expansion coefficient, except that a magnetic field was applied. In Examples 2, 3, 8 and 10, X-ray measurement was performed as in Example 1.

### Example 9

A sample was obtained to measure the linear expansion coefficient in the same manner as in Example 1, except that in the step of <Magnetic field application and preliminary drying>, in a glass petri dish, after a copper foil (surface roughness Rz 1.4 μm) having a thickness of 18 μm and a diameter of 48 mm was placed, the mixture liquid was put in. From the result, it has been found that in the laminate laminated on the copper foil also, anisotropic fillers are oriented resulting from the magnetic field application.

### Comparative Examples 1 to 8, and 11

A dispersion was prepared according to the composition shown in Table 2, and the sample was obtained in the same manner as in Example 1 to measure the linear expansion coefficient, except that in the step of <Magnetic field application and preliminary drying>, no magnetic field was applied. In Comparative Examples 2 to 4 and 11, X-ray measurement was performed as in Example 1.

### Comparative Example 9

A dispersion was prepared according to the composition shown in Table 2, the sample was obtained in the same manner as in Example 1 to measure the linear expansion coefficient, except that in the step of <Magnetic field application and preliminary drying>, no magnetic field was applied, and after the step of <drying>, the magnetic field was applied.

### Comparative Example 10

Using a Labo Plastomill mixer, 71.4 g of PFA powder 1 and 31.6 g of talc 1 were melt-kneaded (time: 600 seconds, temperature: 350° C.), and then naturally cooled to obtain a solid composition. The resulting solid composition was crushed and pelletized. The resulting pellets were press-formed at 350° C. to obtain a resin sheet with a thickness of 0.5 mm. The resin sheet was cut into a 5 mm square to measure the linear expansion coefficient.

TABLE 1

| | | Particle | Aspect | Surface | | | | | |
|---|---|---|---|---|---|---|---|---|---|
| | | size/um | ratio | treatment | Example 1 | Example 2 | Example 3 | Example 4 | Example 5 |
| Composition | Solid content | — | — | — | 50 | 50 | 50 | | 70 |
| (mass %) | in PFA | | | | | | | | |
| | dispersion 1 | | | | | | | | |
| | PFA powder 1 | — | — | — | | | | | |
| | Solid content | — | — | — | | | | 50 | |
| | in PTFE | | | | | | | | |
| | dispersion 1 | | | | | | | | |
| | Talc 1 | 5 | 40-45 | — | 50 | | | 50 | 30 |
| | Talc 2 | 7 | 30 | aminosilane | | 50 | | | |
| | Talc 3 | 5 | 40-45 | aminosilane | | | 50 | | |
| | Boron | 10 | — | — | | | | | |
| | nitride 1 | | | | | | | | |
| | Silica 1 | 2 | spherical | — | | | | | |
| Magnetic field | | — | — | — | 10 | 10 | 10 | 10 | 10 |
| intensity/T | | | | | | | | | |
| Timing of | | — | — | — | during | during | during | during | during |
| magnetic field | | | | | drying of | drying of | drying of | drying of | drying of |
| application | | | | | dispersion | dispersion | dispersion | dispersion | dispersion |
| Copper foil | | — | — | — | absent | absent | absent | absent | absent |
| Linear expansion | | — | — | — | 12 | 27 | 15 | 13 | 43 |
| coefficient in | | | | | | | | | |
| film thickness | | | | | | | | | |
| direction/ppm | | | | | | | | | |
| X-ray | Peak | <001> | | | 12892 | 7926 | 20799 | — | — |
| analysis | intensity | <020> | | | 17037 | 27295 | 16465 | — | — |
| | | <002> | | | — | — | — | — | — |
| | | <100> | | | — | — | — | — | — |
| | Peak | <001>/<020> | | | 0.8 | 0.3 | 1.3 | — | — |
| | intensity | <002>/<100> | | | — | — | — | — | — |
| | ratio | | | | | | | | |
| | | Particle | Aspect | Surface | | | | | Example |
| | | size/um | ratio | treatment | Example 6 | Example 7 | Example 8 | Example 9 | 10 |
| Composition | Solid content | — | — | — | 40 | 40 | 50 | 50 | 50 |
| (mass %) | in PFA | | | | | | | | |
| | dispersion 1 | | | | | | | | |
| | PFA powder 1 | — | — | — | | | | | |
| | Solid content | — | — | — | | | | | |
| | in PTFE | | | | | | | | |
| | dispersion 1 | | | | | | | | |
| | Talc 1 | 5 | 40-45 | — | 60 | 40 | 50 | 50 | |
| | Talc 2 | 7 | 30 | aminosilane | | | | | |
| | Talc 3 | 5 | 40-45 | aminosilane | | | | | |
| | Boron | 10 | — | — | | | | | 50 |
| | nitride 1 | | | | | | | | |
| | Silica 1 | 2 | spherical | — | | 20 | | | |

| | | | | | | | | |
|---|---|---|---|---|---|---|---|---|
| Magnetic field | — | — | — | 10 | 10 | 5 | 10 | |
| intensity/T | | | | | | | | |
| Timing of | — | — | — | during | during | during | during | during |
| magnetic field | | | | drying of | drying of | drying of | drying of | drying of |
| application | | | | dispersion | dispersion | dispersion | dispersion | dispersion |
| Copper foil | — | — | — | absent | absent | absent | present | absent |
| Linear expansion | — | — | — | 11 | 21 | 44 | 22 | 39 |
| coefficient in | | | | | | | | |
| film thickness | | | | | | | | |
| direction/ppm | | | | | | | | |

| X-ray | Peak | <001> | — | — | 154000 | — | — |
|---|---|---|---|---|---|---|---|
| analysis | intensity | <020> | — | — | 6310 | — | — |
| | | <002> | — | — | — | — | 13150 |
| | | <100> | — | — | — | — | 11163 |
| | Peak | <001>/<020> | — | — | 24 | — | — |
| | intensity | <002>/<100> | — | — | — | — | 1.2 |
| | ratio | | | | | | |

TABLE 2

| | | Particle | Aspect | Surface | Comparative | Comparative | Comparative | Comparative | Comparative |
|---|---|---|---|---|---|---|---|---|---|
| | | size/um | ratio | treatment | Example 1 | Example 2 | Example 3 | Example 4 | Example 5 |
| Composition | Solid content | — | — | — | 100 | 50 | 50 | 50 | |
| (mass %) | in PFA | | | | | | | | |
| | dispersion 1 | | | | | | | | |
| | PFA powder 1 | — | — | — | | | | | |
| | Solid content | — | — | — | | | | | 50 |
| | in PTFE | | | | | | | | |
| | dispersion 1 | | | | | | | | |
| | Talc 1 | 5 | 40-45 | — | | 50 | | | 50 |
| | Talc 2 | 7 | 30 | aminosilane | | | 50 | | |
| | Talc 3 | 5 | 40-45 | aminosilane | | | | 50 | |
| | Boron | 10 | — | — | | | | | |
| | nitride 1 | | | | | | | | |
| | Silica 1 | 2 | spherical | — | | | | | |
| Magnetic field | | | — | — | 0 | 0 | 0 | 0 | 0 |
| intensity/T | | | | | | | | | |
| Timing of | | | — | — | absent | absent | absent | absent | absent |
| magnetic field | | | | | | | | | |
| application | | | | | | | | | |
| Copper foil | | | — | — | absent | absent | absent | absent | absent |
| Linear expansion | | | — | — | (210) | 94 | 108 | 81 | 123 |
| coefficient in | | | | | | | | | |
| film thickness | | | | | | | | | |
| direction/ppm | | | | | | | | | |
| X-ray | Peak | <001> | | | — | 18700000 | 28600000 | 26900000 | — |
| analysis | intensity | <020> | | | — | 4566 | 34227 | 42288 | — |
| | | <002> | | | — | — | — | — | — |
| | | <100> | | | — | — | — | — | — |
| | Peak | <001>/<020> | | | — | 4095 | 836 | 636 | — |
| | intensity | <002>/<100> | | | — | — | — | — | — |
| | ratio | | | | | | | | |

| | | Particle | Aspect | Surface | Comparative | Comparative | Comparative |
|---|---|---|---|---|---|---|---|
| | | size/um | ratio | treatment | Example 6 | Example 7 | Example 8 |
| Composition | Solid content | — | — | — | 70 | 40 | 40 |
| (mass %) | in PFA | | | | | | |
| | dispersion 1 | | | | | | |
| | PFA powder 1 | — | — | — | | | |
| | Solid content | — | — | — | | | |
| | in PTFE | | | | | | |
| | dispersion 1 | | | | | | |
| | Talc 1 | 5 | 40-45 | — | 30 | 60 | 40 |
| | Talc 2 | 7 | 30 | aminosilane | | | |
| | Talc 3 | 5 | 40-45 | aminosilane | | | |
| | Boron | 10 | — | — | | | |
| | nitride 1 | | | | | | |
| | Silica 1 | 2 | spherical | — | | | 20 |
| Magnetic field | | | — | — | 0 | 0 | 0 |
| intensity/T | | | | | | | |
| Timing of | | | — | — | absent | absent | absent |
| magnetic field | | | | | | | |
| application | | | | | | | |
| Copper foil | | | — | — | absent | absent | absent |
| Linear expansion | | | — | — | 149 | 77 | 103 |
| coefficient in | | | | | | | |
| film thickness | | | | | | | |
| direction/ppm | | | | | | | |
| X-ray | Peak | <001> | | | — | — | — |
| analysis | intensity | <020> | | | — | — | — |
| | | <002> | | | — | — | — |
| | | <100> | | | — | — | — |
| | Peak | <001>/<020> | | | — | — | — |
| | intensity | <002>/<100> | | | — | — | — |
| | ratio | | | | | | |

| | | Particle | Aspect | Surface | Comparative | Comparative | Comparative |
|---|---|---|---|---|---|---|---|
| | | size/um | ratio | treatment | Example 9 | Example 10 | Example 11 |
| Composition | Solid content | — | — | — | 50 | | 50 |
| (mass %) | in PFA | | | | | | |
| | dispersion 1 | | | | | | |
| | PFA powder 1 | — | — | — | | 70 | |
| | Solid content | — | — | — | | | |
| | in PTFE | | | | | | |
| | dispersion 1 | | | | | | |
| | Talc 1 | 5 | 40-45 | — | 50 | 30 | |
| | Talc 2 | 7 | 30 | aminosilane | | | |
| | Talc 3 | 5 | 40-45 | aminosilane | | | |
| | Boron | 10 | — | — | | | 50 |
| | nitride 1 | | | | | | |
| | Silica 1 | 2 | spherical | — | | | |

| | | | | | |
|---|---|---|---|---|---|
| Magnetic field | — | — | 10 | 10 | 0 |
| intensity/T | | | | | |
| Timing of | — | — | after | after | absent |
| magnetic field | | | drying of | melting/ | |
| application | | | dispersion | kneading | |
| Copper foil | — | — | absent | absent | absent |
| Linear expansion | — | — | 99 | 155 | 106 |
| coefficient in | | | | | |
| film thickness | | | | | |
| direction/ppm | | | | | |

| | | | | | |
|---|---|---|---|---|---|
| X-ray | Peak | <001> | — | — | — |
| analysis | intensity | <020> | — | — | — |
| | | <002> | — | — | 77344 |
| | | <100> | — | — | 3403 |
| | Peak | <001>/<020> | — | — | — |
| | intensity | <002>/<100> | — | — | 23 |

ratio

The relationship between the Examples and Comparative Examples described above is shown as a comparison in the following Table 3, wherein the resin sheet was obtained by sintering a dried coating film without applying a magnetic field in Comparative Examples relative to Examples. Based on the comparison, the ratio between linear expansion coefficients in the film thickness direction (Linear expansion coefficient in film thickness direction of resin sheet applied with magnetic field/Linear expansion coefficient of resin sheet without application of magnetic field) was calculated, and the values are shown in Table 3.

TABLE 3

| | Magnetic field application | | | | |
|---|---|---|---|---|---|
| | Example 1 | Example 2 | Example 3 | Example 4 | Example 5 |
| | Without magnetic field application | | | | |
| | Comparative | Comparative | Comparative | Comparative | Comparative |
| | Example 2 | Example 3 | Example 4 | Example 5 | Example 6 |
| Ratio of | 0.13 | 0.25 | 0.19 | 0.11 | 0.29 |
| linear | | | | | |
| expansion | | | | | |
| coefficients | | | | | |
| in film | | | | | |
| thickness | | | | | |
| direction | | | | | |

| | Magnetic field application | | | | |
|---|---|---|---|---|---|
| | Example 6 | Example 7 | Example 8 | Example 9 | Example 10 |
| | Without magnetic field application | | | | |
| | Comparative | Comparative | Comparative | Comparative | Comparative |
| | Example 7 | Example 8 | Example 2 | Example 2 | Example 11 |
| Ratio of | 0.14 | 0.20 | 0.47 | 0.23 | 0.37 |
| linear | | | | | |
| expansion | | | | | |
| coefficients | | | | | |
| in film | | | | | |
| thickness | | | | | |
| direction | | | | | |

From the results of Examples each in Tables 1 to 3, it is apparent that the resin sheet of the present disclosure has excellent thermal shrinkage properties in the thickness direction.

### INDUSTRIAL APPLICABILITY

The resin sheet of the present disclosure can be suitably used in circuit board applications.

### EXPLANATION OF REFERENCES

1: Superconducting coil
2: Sample stage
3: Sample
4: Magnetic field
5: Cross section of sheet
6: Thickness direction of sheet
7: Beam irradiation position
8: Hole
9: Sample holder

1. A resin sheet comprising a fluororesin and an anisotropic filler, wherein the anisotropic filler is uniaxially oriented in the film thickness direction and randomly oriented in the plane direction.

2. The resin sheet according to claim 1, wherein the fluororesin is a perfluorinated fluororesin.

3. The resin sheet according to claim 1, wherein the perfluorinated fluororesin is at least one selected from the group consisting of polytetrafluoroethylene, tetrafluoroethylene/perfluoro (alkyl vinyl ether) copolymer, and tetrafluoroethylene/hexafluoropropylene copolymer.

4. The resin sheet according to claim 1, wherein the anisotropic filler has an aspect ratio of 1 or more and 200 or less.

5. The resin sheet according to claim 1, wherein the anisotropic filler has an average particle size of 0.1 to 50 μm.

6. The resin sheet according to claim 1, wherein the anisotropic filler is talc or boron nitride.

7. The resin sheet according to claim 6, wherein, in an X-ray diffraction chart obtained by exposure of the sheet in a cross-sectional direction to X-rays, the anisotropic filler is talc, and an intensity ratio (<001>/<020>) of a diffraction peak of a <001>plane to a diffraction peak of a <020>plane of the talc in a thickness direction of the sheet is 300 or less; or the anisotropic filler is boron nitride, and an intensity ratio (<002>/<100>) of a diffraction peak of a <002>plane to a diffraction peak of a <100>plane of the boron nitride in the thickness direction of the sheet is 20 or less.

8. The resin sheet according to claim 1, further comprising silica or glass fiber in addition to the anisotropic filler.

9. The resin sheet according to claim 8, wherein the silica is amorphous.

10. The resin sheet according to claim 1, having a film thickness of 0.1 to 2 mm.

11. The resin sheet according to claim 1, being an insulating material for a circuit board.

12. A copper-clad laminate comprising a copper foil and the resin sheet according to claim 1 as essential layers.

13. A circuit board comprising the resin sheet according to claim 1 and a conductive layer.

14. The circuit board according to claim 13, wherein the conductive layer is made of metal.

15. The circuit board according to claim 14, wherein the metal has a surface roughness Rz of 2.0 μm or less on a surface in contact with the resin sheet.

16. The circuit board according to claim 14, wherein the metal is copper.

17. The circuit board according to claim 16, wherein the copper is rolled copper or electrolytic copper.

18. The circuit board according to claim 13, being any one of a printed circuit board, a multilayer circuit board or a high frequency board.

19. A method for producing a resin sheet, comprising:
(1) applying a dispersion containing a fluororesin and an anisotropic filler onto a substrate to form a coating film;
(2) drying the coating film obtained in (1) while applying a magnetic field to obtain a dried coating film;
and
(3) sintering the dried coating film obtained in (2).

20. The method for producing a resin sheet according to claim 19, wherein a linear expansion coefficient in the film thickness direction is equal to or less than ½ that of a resin sheet obtained by sintering a coating film dried without application of a magnetic field in (2).

21. The method for producing a resin sheet according to claim 19, wherein a strength of the magnetic field is 0.1 to 10 T.

22. The method for producing a resin sheet according to claim 19, wherein a total solid concentration of the fluororesin and the anisotropic filler in the dispersion is 5 to 70 wt %.

23. The method for producing a resin sheet according to claim 19, wherein a weight ratio between the fluororesin and the anisotropic filler in the dispersion is 90/10 to 30/70.
